(19) United States
(12) Patent Application Publication
(10) Pub. No.: US 2002/0168799 A1
(43) Pub. Date: Nov. 14, 2002

(54) Die mounting on a substrate

(76) Inventor: Kamran Manteghi, San Jose, CA (US)

Correspondence Address: CORPORATE PATENT COUNSEL, PHILIPS NORTH AMERICA CORPORATION, 580 WHITE PLAINS ROAD, TARRYTOWN, NY, 10591, US

(21) Appl. No.: 09/851,965

(22) Filed: May 10, 2001

(51) Int. Cl. H01L 21/48

(52) U.S. Cl. 438/125

(57) ABSTRACT

A reduction in encapsulation height for semiconductor devices is obtained by forming a cavity in a substrate carrying a conductive pattern on an upper surface, and attaching a die to the bottom surface of the substrate, connecting pads on the die exposed within the cavity. Wire bonds connect the connecting pads to the conductive pattern, the wire bonds extending into the cavity.

This invention relates to an improved die mounting on a substrate and particularly to ball grid arrays for chip packaging, and to a method of producing such a mounting.

### BACKGROUND OF THE INVENTION

Flex ball grid arrays (FBGA) or fine pitch ball grid arrays (FPBGA) are packages in which an IC chip is mounted, for example on a polyimide tape, or some other substrate, on which a circuit pattern has been formed. The wires are bonded to the substrate. The entire assembly is encapsulated by molding with an epoxy compound.

With the move towards smaller and thinner packaging, manufacturing becomes a challenge. This is not only the case with mounting on a tape, but to other mounting procedures also.

### BRIEF DESCRIPTION OF THE DRAWINGS

FIG. 1 is a diagrammatic cross-section through a substrate and a die positioned ready for attachment;

FIG. 2 is a similar cross-section, die attached;

FIG. 3 is a similar cross-section, with wire bonding carried out;

FIG. 4 is a similar cross-section, showing molding of the substrate;

FIG. 5 is a similar cross-section, showing attachment of solder balls; and

FIG. 6 is a similar cross-section, showing the assembled item ready for attachment to a circuit.

### DETAILED DESCRIPTION OF THE PREFERRED EMBODIMENT

With the present invention, a substrate cavity is formed and the top of the die is attached to the bottom side of the substrate so that the bonding pads are exposed through the cavity. As the die is attached on the bottom surface, the wire conductor loops can be made lower. As a result the encapsulation height is reduced. Thus, according to the present invention, an improved die mounting comprises a substrate having a conductive pattern on a top surface, a cavity extending through the substrate, a die mounted on the bottom surface of the substrate, beneath the cavity, and bonding wires extending from contact pads on the die through the cavity to the conductive pattern. The substrate can be flexible, for example a polyimide tape.

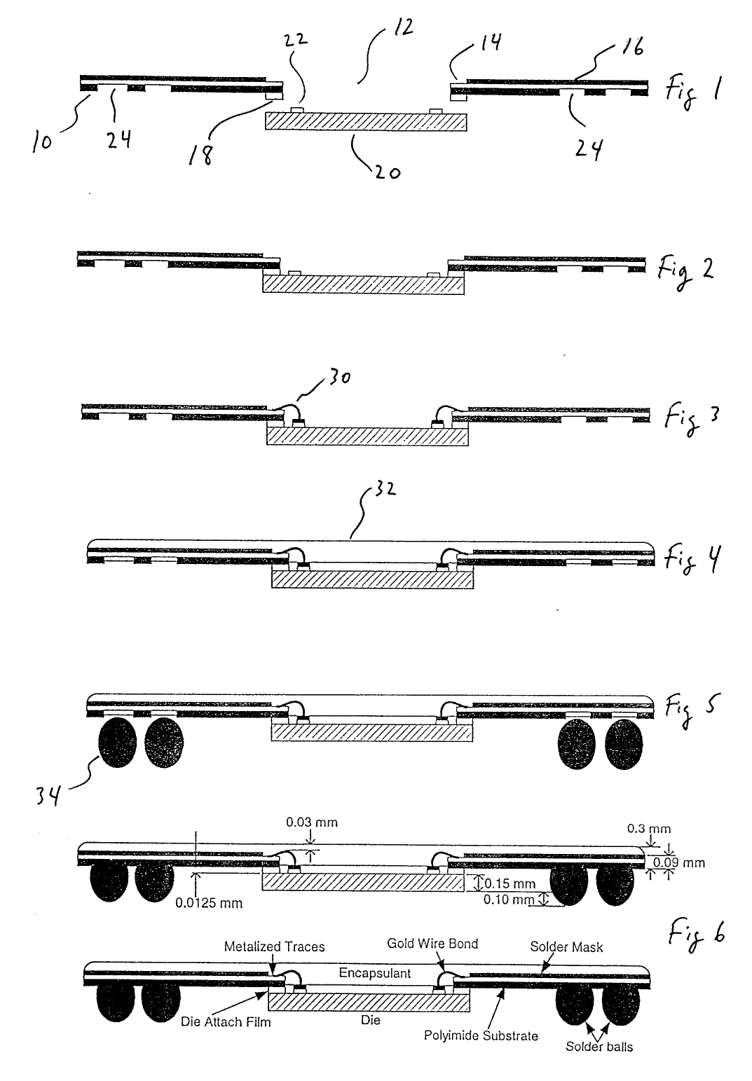

As illustrated in FIG. 1, a substrate 10 has a cavity 12 formed therein, as by punching or etching. A conductive pattern 14 is formed on the top surface of the substrate 10, and a solder mask 16 is formed on the pattern 14. An adhesive 18 is deposited on the underside of the substrate 10 adjacent the periphery of the cavity 12. In FIG. 1 a die 20 is positioned beneath the substrate prior to attachment thereto. On the upper surface of the die 20 are contact pads 22. Apertures 24 are formed in the substrate 10 for access to the conductive pattern 14.

In FIG. 2 the die 20 is shown attached to the substrate 10 by the adhesive 18. It will be seen that the contact pads 22 are within the periphery of the cavity 12.

In FIG. 3 the contact pads 22 are shown wire bonded to the pattern 14 by wire bonds 30. In FIG. 4, the substrate has been molded by encapsulating material 32.

FIG. 5 shows solder balls 34 positioned at the apertures 24, while in FIG. 6 the solder balls are shown in contact with the conductive pattern 14, ready for mounting of the device comprising the die 20 and substrate 10 on to some form of circuit pattern by conventional means.

Some typical dimensions are; die thickness 0.15 mm, glue pad thickness 0.0125 mm, total thickness of the substrate, conductive pattern and solder mask 0.09 mm, and thickness of material 30 over the solder mask 0.3 mm. A thickness of 0.03 mm of material 30 is obtained over the bonding wires 30.

It will be seen that by attaching the die below the substrate and accessing through a cavity in the substrate, a lower profile is obtained for the bonding wires.

The overall thickness of substrate plus die remains the same, but with the die mounted on top of the substrate, the bonding wires will project above this overall thickness considerably more than in the invention. As a further feature, with the die mounted on top of the substrate, the thickness of the encapsulating material 32 will need to be thicker than that required in the present invention, providing both a cost saving and a reduction in package assembly height.

In producing a package in accordance with the present invention, a substrate, which can be of any conventional form, with varying conductive patterns thereon, has a cavity, or a plurality of cavities, formed therein, as by stamping or etching. Conveniently, or as desired, the cavities can be formed before or after the forming of the conductive layers, plus other layers, or at some intermediate stage.

The substrate can be rigid, flexible, or other form, although the invention is particularly applicable for FBGA or FPBGA packages in which the die is mounted on a polyimide tape which forms the substrate.

The conductive pattern 14 can have metallized areas, for example gold, to which the bonding wires are attached. The bonding wires 30 are normally gold.

Numerous other embodiments may be envisaged without departing from the spirit or scope of the invention.

What is claimed is:

1. An improved die mounting on a substrate, comprising:
a substrate having top and bottom surfaces;
a conductive pattern on said top surface of said substrate;
a cavity formed in said substrate and extending through said substrate;
a die attached to the bottom surface of said substrate, beneath said cavity, said die having contact pads on the upper surface and positioned within said cavity;
bonding wires extending between said contact pads and said conductive pattern.

2. A mounting as claimed in claim 1, said substrate being flexible.

3. A mounting as claimed in claim 1, said substrate being a polyimide tape.

4. A mounting as claimed in claim 1, including apertures in said substrate extending through to said conductive pattern.

5. A mounting as claimed in claim 4, including solder balls positioned at said apertures and connecting to said conductive pattern.

6. A method of mounting a die on a substrate, comprising;
forming a cavity in a substrate, extending through said substrate;
mounting a die on a bottom surface of said substrate, beneath said cavity;
connecting bonding wires between contact pads on said die and a conductive pattern on a top surface of said substrate, said bonding wires extending into said cavity.

7. A method as claimed in claim 6, including mounting said die on a flexible substrate.

8. A method as claimed in claim 6, including mounting said die on a polyimide tape substrate.

9. A method as claimed in claim 6, including forming apertures in said substrate, extending through said substrate to said conductive pattern.

10. A method as claimed in claim 9, including attaching solder balls to said conductive pattern in said apertures.
